(19) United States
(12) Patent Application Publication
(10) Pub. No.: US 2026/0123532 A1
(43) Pub. Date: Apr. 30, 2026

(54) SEMICONDUCTOR PACKAGES WITH PLASMA-ETCHED SCALLOPS

(71) Applicant: TEXAS INSTRUMENTS INCORPORATED, Dallas, TX (US)

(72) Inventors: Daiki KOMATSU, Beppu-Shi Oita-Ken (JP); Kashyap MOHAN, McKinney, TX (US)

(21) Appl. No.: 18/934,039

(22) Filed: Oct. 31, 2024

(51) Int. Cl. H01L 25/065; B81B 3/00; H01L 21/3065; H01L 23/00; H01L 23/02; H01L 23/13; H01L 25/00

(52) U.S. Cl. CPC H10W 90/00; B81B 3/0021; H10P 50/242; H10W 70/68; B81B 2201/0257; H10W 72/581; H10W 72/884; H10W 76/10; H10W 90/734; H10W 90/754

(57) ABSTRACT

In examples, a semiconductor package includes a substrate including a first opening; a first semiconductor die coupled to the substrate and including a microelectromechanical systems (MEMS) membrane, the first semiconductor die including a scalloped outer surface having multiple concavities; a second semiconductor die coupled to the substrate and configured to control the first semiconductor die; bond wires coupling the first and second semiconductor dies to the substrate; and a protective enclosure covering the substrate, the first and second semiconductor dies, and the bond wires.

### BACKGROUND

Semiconductor chips are often housed inside semiconductor packages that protect the chips from deleterious environmental influences, such as heat, moisture, and debris. A packaged chip communicates with electronic devices outside the package via conductive terminals, such as leads, that are exposed to surfaces of the package. Within the package, the chip may be electrically coupled to the conductive terminals using any suitable technique, such as by wire bonding.

### SUMMARY

In examples, a semiconductor package includes a substrate including a first opening; a first semiconductor die coupled to the substrate and including a microelectromechanical systems (MEMS) membrane, the first semiconductor die including a scalloped outer surface having multiple concavities; a second semiconductor die coupled to the substrate and configured to control the first semiconductor die; bond wires coupling the first and second semiconductor dies to the substrate; and a protective enclosure covering the substrate, the first and second semiconductor dies, and the bond wires.

In examples, a method for manufacturing a semiconductor package includes applying a wafer bond layer to a microelectromechanical systems (MEMS) membrane on a first surface of a semiconductor wafer and to an oxide layer on the first surface of the semiconductor wafer; coupling a carrier wafer to the wafer bond layer; coupling a photoresist layer to a second surface of the semiconductor wafer opposite the first surface; patterning the photoresist layer to include a first opening above a first portion of the semiconductor wafer, a second opening above a second portion of the semiconductor wafer, and a third opening between the first and second openings; simultaneously plasma etching a first opening in the first portion through the first opening in the photoresist layer, a second opening in the second portion through the second opening in the photoresist layer, and a third opening in the semiconductor wafer between the first and second openings through the third opening in the photoresist layer, the plasma etching causing walls of the first, second, and third openings in the semiconductor wafer to be scalloped with multiple concavities having heights ranging from 20 nanometers to 1 micron, and the plasma etching of the third opening causing the first and second portions to separate from each other; removing first, second, and third segments of the oxide layer from the first, second, and third openings, respectively; removing the photoresist layer, the carrier wafer, and the wafer bond layer; coupling the first portion to a substrate; and covering the first portion and the substrate with a protective enclosure.

### BRIEF DESCRIPTION OF THE DRAWINGS

FIG. 1A is a multiplanar cross-sectional view of a semiconductor package with plasma-etched scallops, in accordance with various examples.

FIG. 1B is a top-down view of a semiconductor package with plasma-etched scallops, in accordance with various examples.

FIG. 1C is a bottom-up view of a semiconductor package with plasma-etched scallops, in accordance with various examples.

FIG. 1D is a perspective view of a semiconductor package with plasma-etched scallops, in accordance with various examples.

FIGS. 1E and 1F are perspective views of plasma-etched scalloped surfaces on a semiconductor package, in accordance with various examples.

FIG. 2 is a flow diagram of a method for manufacturing a semiconductor package with plasma-etched scallops, in accordance with various examples.

FIGS. 3A1, 3A2, 3B1, 3B2, 3C1, 3C2, 3D1, 3D2, 3E1, 3E2, 3F1, 3F2, 3G1, 3G2, 3H1, 3H2, 3I1, 3I2, 3J1, 3J2, 3K1, 3K2, 3L1, 3L2, 3M1, 3M2, 3N1, 3N2, and 3O are a process flow for manufacturing a semiconductor package with plasma-etched scallops, in accordance with various examples.

FIG. 4 is a block diagram of an electronic device including a semiconductor package with plasma-etched scallops, in accordance with various examples.

### DETAILED DESCRIPTION

Semiconductor packages are typically manufactured in bulk. During the manufacturing process, a cutting tool, such as a mechanical saw or laser saw, is used to separate a semiconductor wafer to individual semiconductor dies in a process known as singulation.

Different applications may benefit from different types of cutting tools. For example, delicate, high-precision devices such as microelectromechanical systems (MEMS) semiconductor dies may require singulation by laser saw instead of mechanical saw, because laser saws provide greater precision and accuracy and reduced mechanical stress relative to mechanical saws. Laser saws are used to scribe semiconductor wafers to facilitate the subsequent separation of the wafers into individual semiconductor dies, such as by using a flex frame.

Laser saws, however, require the scribe streets (the scribing area on a semiconductor wafer between two consecutively adjacent semiconductor dies) to be of a minimum width (e.g., 90 microns), particularly in the context of specific types of MEMS devices. Using a laser saw on scribe streets narrower than this minimum width can result in structural and operational damage during the singulation process. Because laser sawing requires scribe streets of a minimum width, the laser sawing technique impedes the continued reductions in MEMS device sizes being achieved in the industry. Stated another way, the semiconductor industry would be capable of producing smaller MEMS devices (e.g., MEMS microphones) were it not for the fact that laser saws require wide scribe streets. Because the scribe streets must be wide to accommodate laser saws, the resulting MEMS devices are also undesirably large. Consequently, electronic devices are heavier, costlier, and occupy more volume than would be the case if wide scribe streets were not required.

This disclosure describes various examples of a semiconductor package manufacturing technique useful to singulate MEMS semiconductor wafers without laser saws. Because this manufacturing technique eliminates the use of laser saws, the minimum width of scribe streets is substantially reduced. Because the scribe streets do not have a minimum required width, the challenges caused by wide scribe streets, such as heavier, costlier, and more voluminous electronic devices, are mitigated. Furthermore, irrespective of the particular application or MEMS device type, the reduction of scribe street widths increases the number of semiconductor dies that can be produced from each semiconductor wafer, thereby substantially increasing manufacturing yield.

In examples, a method for manufacturing a semiconductor package includes applying a wafer bond layer to a microelectromechanical systems (MEMS) membrane on a first surface of a semiconductor wafer and to an oxide layer on the first surface of the semiconductor wafer. The method includes coupling a carrier wafer to the wafer bond layer and coupling a photoresist layer to a second surface of the semiconductor wafer opposite the first surface. The method includes patterning the photoresist layer to include a first opening above a first portion of the semiconductor wafer, a second opening above a second portion of the semiconductor wafer, and a third opening in between the first and second openings. The method includes simultaneously plasma etching a first opening in the first portion through the first opening in the photoresist layer, a second opening in the second portion through the second opening in the photoresist layer, and a third opening in the semiconductor wafer between the first and second openings. The plasma etching causes walls of the first, second, and third openings to be scalloped with multiple concavities having heights ranging from 20 nanometers to 1 micron, and the plasma etching of the third opening causes the first and second portions to separate from each other. The method includes removing first, second, and third segments of the oxide layer from the first, second, and third openings, respectively. The method also includes removing the photoresist layer, the carrier wafer, and the wafer bond layer, coupling the first portion to a substrate, and covering the first portion and the substrate with a protective enclosure.

In examples, a semiconductor package manufactured according to this technique includes a substrate and a semiconductor die coupled to the substrate and having multiple scalloped outer lateral surfaces, scalloped inner lateral surface, a non-scalloped top surface, and a non-scalloped bottom surface. The multiple scalloped outer lateral surfaces include a concavity that continuously extends along each of the outer lateral surfaces. The semiconductor package also includes a protective enclosure covering the substrate and the semiconductor die.

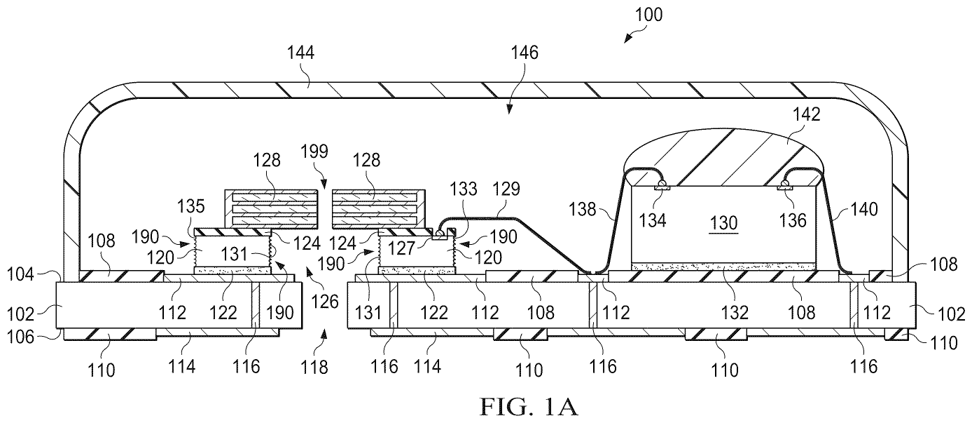

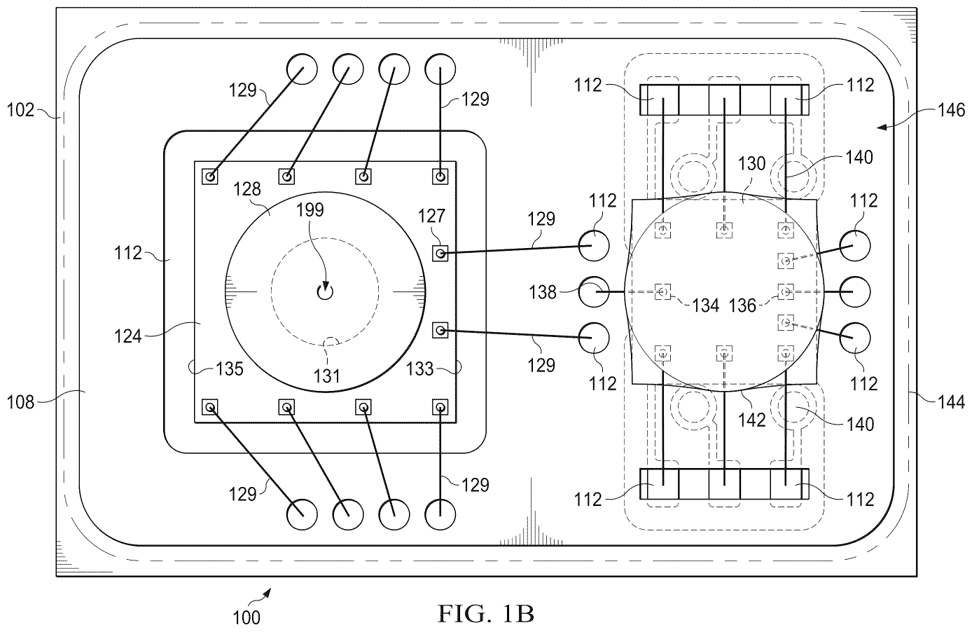

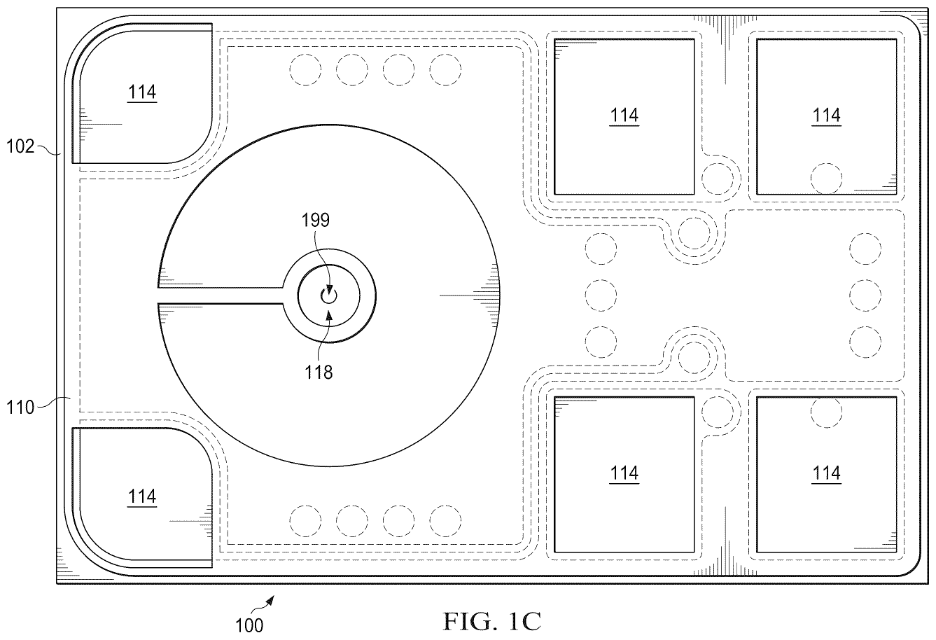

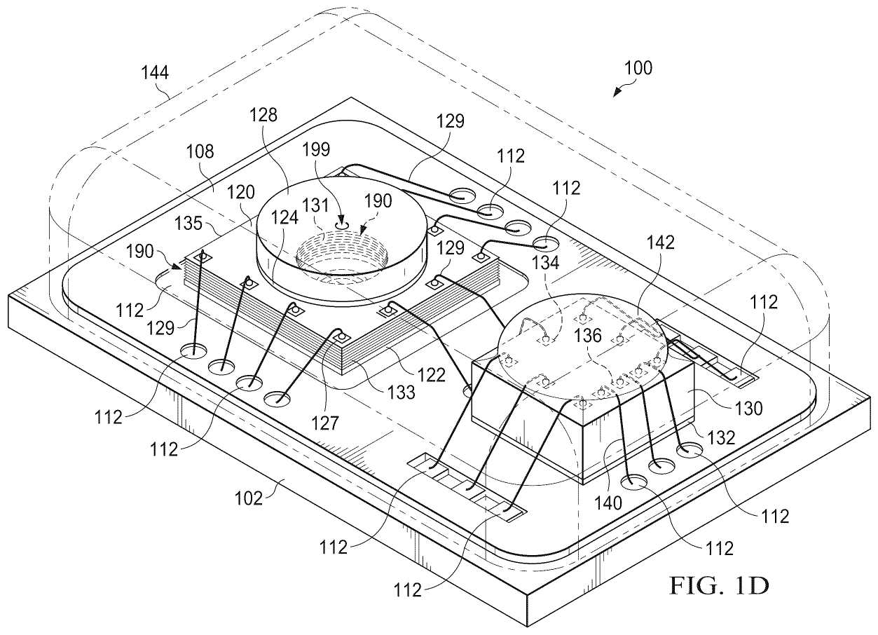

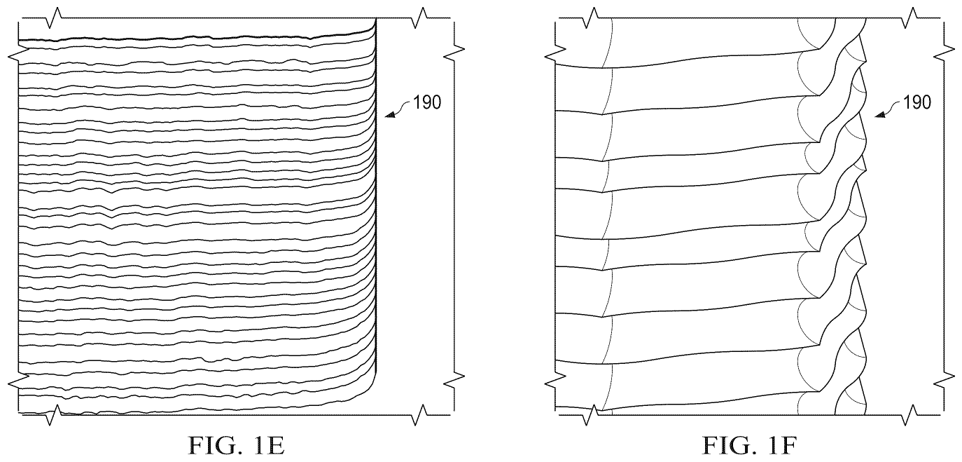

FIG. 1A is a multiplanar cross-sectional view of a semiconductor package 100 with plasma-etched scallops, in accordance with various examples. FIGS. 1B, 1C, and 1D are top-down, bottom-up, and perspective views, respectively, of the example semiconductor package 100. The semiconductor package 100 includes a substrate 102 (e.g., ceramic, glass, a semiconductor such as silicon) having a top surface 104 and a bottom surface 106. A solder resist layer 108 contacts portions of the top surface 104, and a solder resist layer 110 contacts portions of the bottom surface 106. A metal layer 112 contacts portions of the top surface 104, and a metal layer 114 contacts portions of the bottom surface 106. In examples, the solder resist layer 108 covers portions of the top surface 104 not covered by the metal layer 112, and the solder resist layer 110 covers portions of the bottom surface 106 not covered by the metal layer 114. The metal layers 112, 114 may be coupled to each other by metal vias 116 that extend through the substrate 102. An opening 118 extends through the substrate 102.

A semiconductor die 120 (e.g., silicon, gallium nitride) is coupled to the metal layer 112 by a die attach material 122. In examples, the semiconductor die 120 is a microelectromechanical systems (MEMS) die and measures approximately 1.4 millimeters by 1.4 millimeters or less, and this range of small die sizes is enabled specifically because of the manufacturing techniques described herein. In examples, the die attach material 122 is a non-conductive die attach material, such as an epoxy resin or silicone. An opening 126 extends through the semiconductor die 120. A MEMS element 128, such as a MEMS membrane (e.g., an acoustic membrane, such as in a MEMS microphone) is coupled to the semiconductor die 120 by an oxide layer 124, such as silicon dioxide. An opening 199 extends through the MEMS element 128.

In examples, the openings 118, 126, and 199 have circular, ovoid, or polygonal (e.g., rectangular) horizontal cross-sectional shapes. In examples, the openings 118, 126, and 199 have the same horizontal cross-sectional shape. In other examples, the openings 118, 126, and 199 have differing horizontal cross-sectional shapes. In other examples, at least some of the openings 118, 126, and 199 have the same horizontal cross-sectional shapes, or, alternatively, at least some of the openings 118, 126, and 199 have differing horizontal cross-sectional shapes. The openings 118, 126, and 199 are in fluidic communication with each other, meaning that the same instance of fluid or gas could flow through all three of the openings 118, 126, and 199. The openings 118, 126, and 199 may be arranged consecutively with no other openings therebetween.

The semiconductor die 120 includes a bond pad 127. A bond wire 129 couples the bond pad 127 to the metal layer 112.

The semiconductor package 100 may include a semiconductor die 130, such as a driver or controller die that is configured to control the semiconductor die 120. The semiconductor die 130 is coupled to the substrate 102 by a die attach material 132. In examples, the die attach material 132 is a non-conductive die attach material, such as an epoxy resin or silicone. The semiconductor die 130 includes bond pads 134 and 136. A bond wire 138 couples the bond pad 134 to the metal layer 112. A bond wire 140 couples the bond pad 136 to the metal layer 112. A glob top 142 covers the top surface of the semiconductor die 130, including the bond pads 134 and 136 and portions of the bond wires 138 and 140. A cover 144 defines a cavity 146 in which the various aforementioned structures are positioned.

The semiconductor die 120 includes an inner lateral surface 131 and outer lateral surfaces 133 and 135. In examples, the inner lateral surface 131 is rounded, meaning that the inner lateral surface 131 forms an approximate circle when viewed from above or below (i.e., in a horizontal cross-section). In other examples, the inner lateral surface 131 may be straight (e.g., non-rounded) and multi-sided, meaning that the inner lateral surface 131 may include multiple sub-surfaces meeting each other at approximately right angles. The inner lateral surface 131 is scalloped with multiple concavities having heights ranging from 20 nanometers to 1 micron. Similarly, the outer lateral surfaces 133 and 135 are scalloped with multiple concavities having heights ranging from 20 nanometers to 1 micron. Additional lateral surfaces of the semiconductor die 120 that are not visible in the view of FIG. 1A also may be scalloped with multiple concavities having heights ranging from 20 nanometers to 1 micron. Excursions above the 20 nanometer to 1 micron range are disadvantageous because they result in lateral etching and thus a loss of verticality of the surface being etched, which is problematic with respect to process requirements, and excursions below this range are disadvantageous because they significantly decrease etch throughput (e.g., they increase the etching time).

FIGS. 1E and 1F are perspective views of plasma-etched scalloped surfaces on a semiconductor package, in accordance with various examples. Specifically, FIGS. 1E and 1F provide detailed views of the scalloped surfaces described above, such as the inner lateral surface 131 and/or the outer lateral surfaces 133 and 135. FIG. 1E provides a larger-scale view of the multiple concavities 190 that form the scalloped surface, while FIG. 1F provides a more detailed view of the multiple concavities 190 that form the scalloped surface.

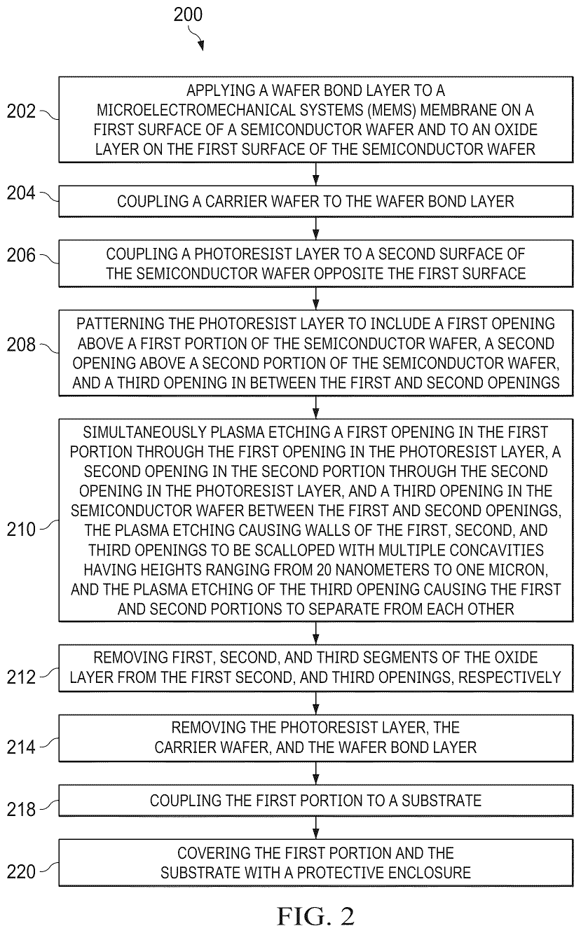

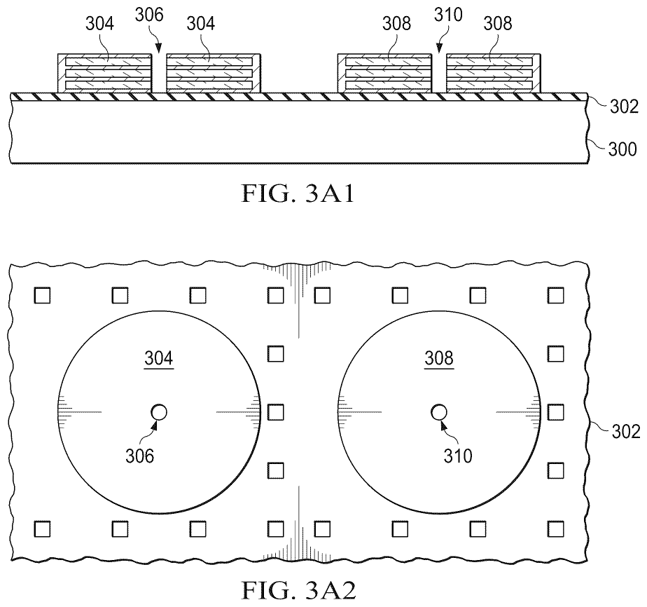

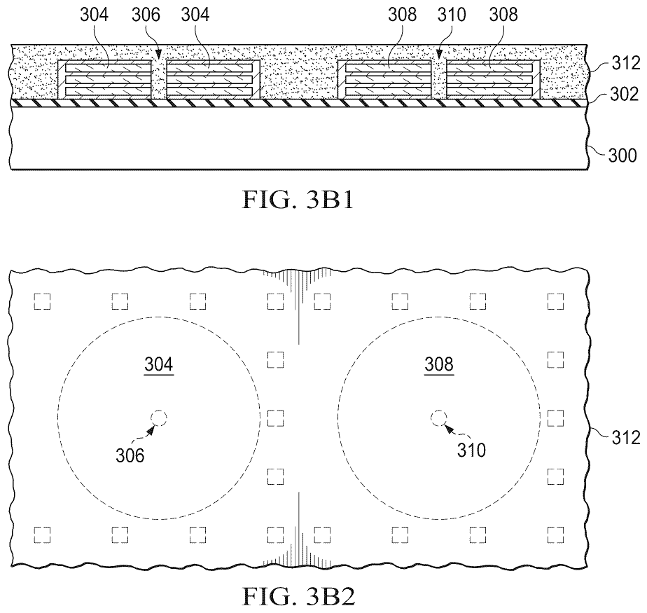

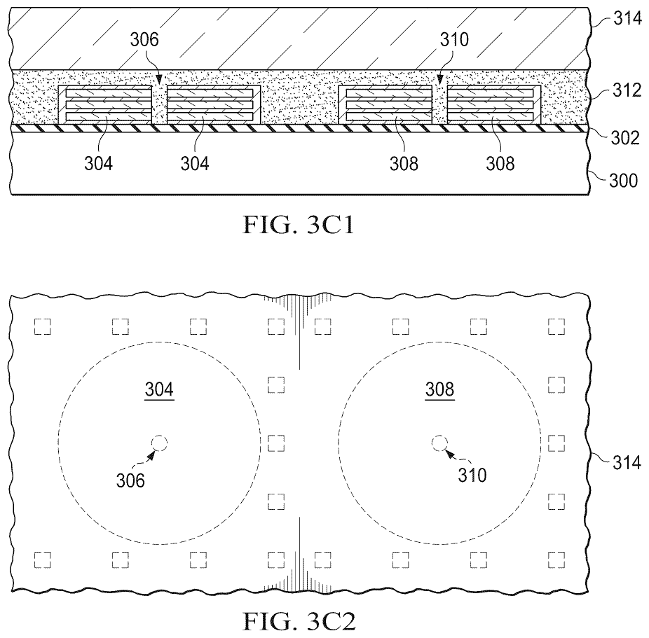

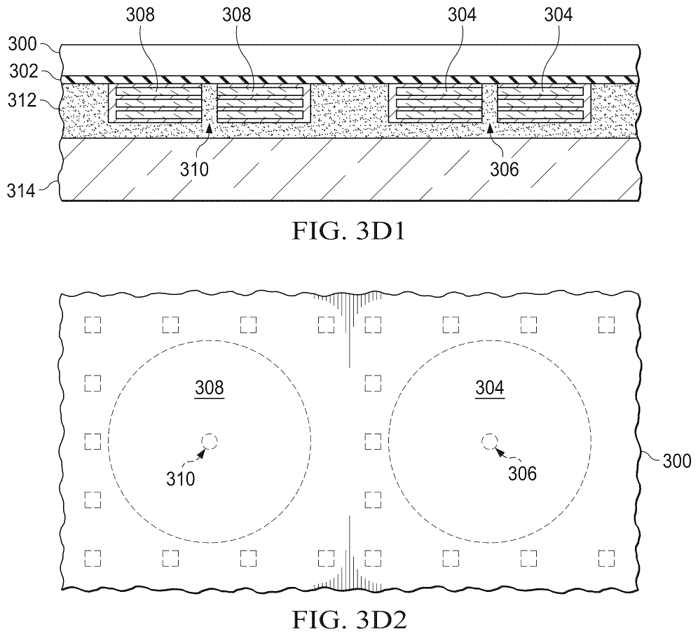

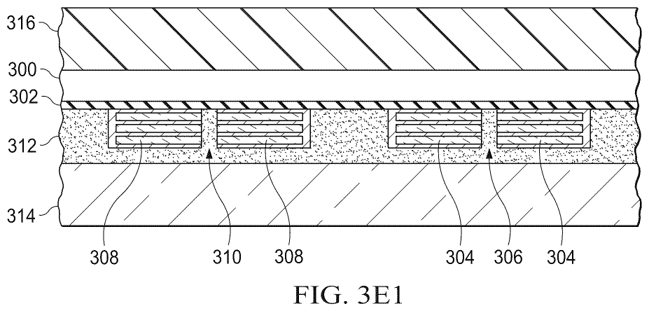

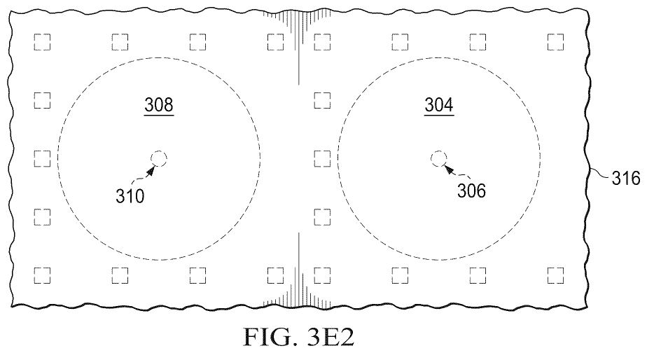

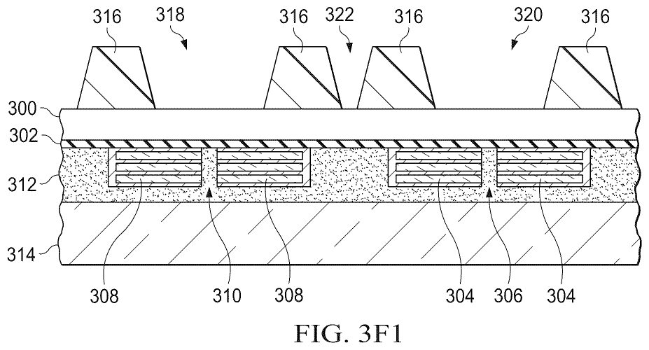

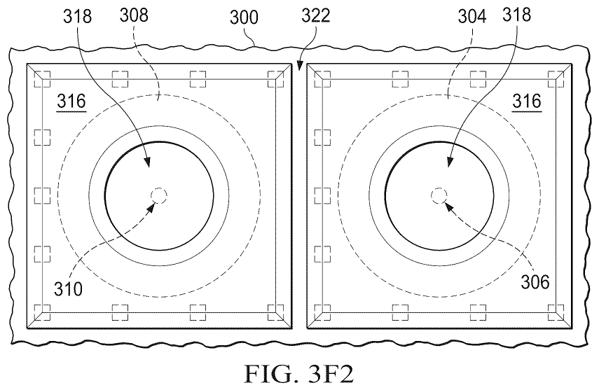

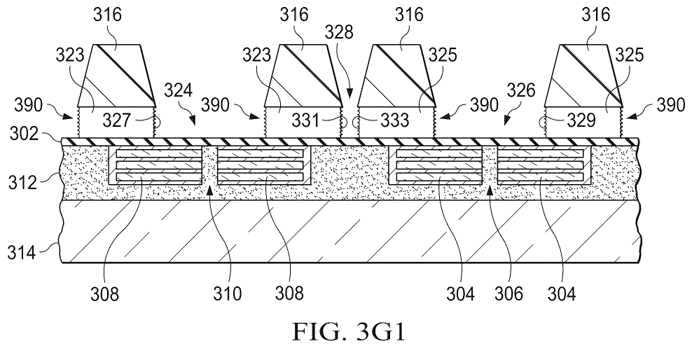

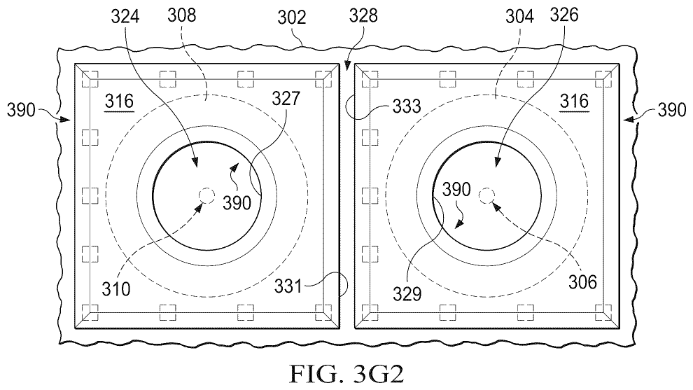

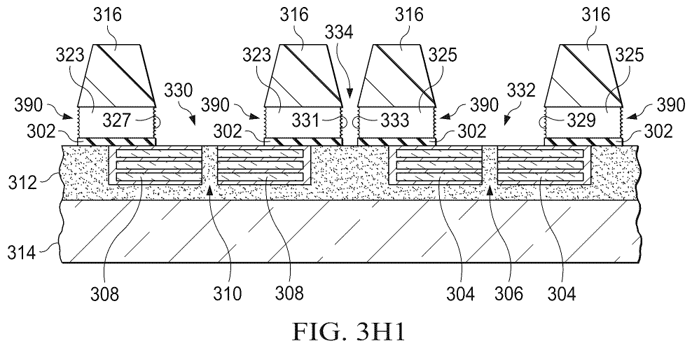

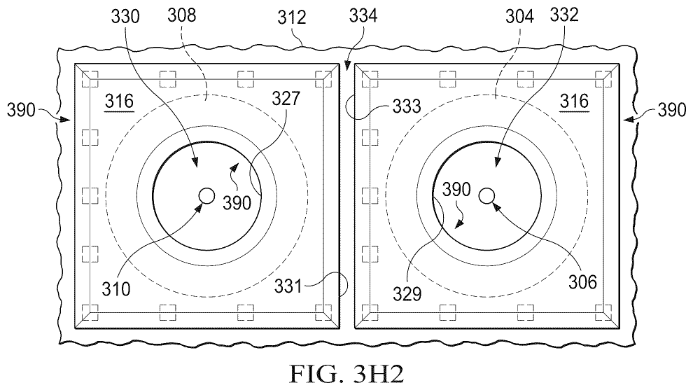

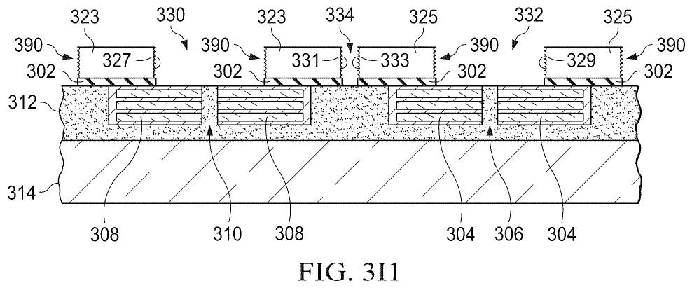

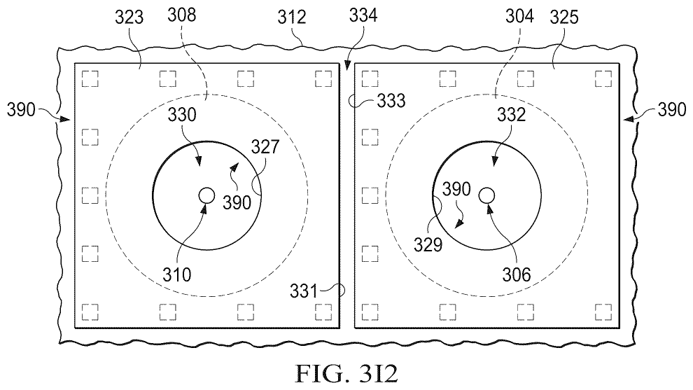

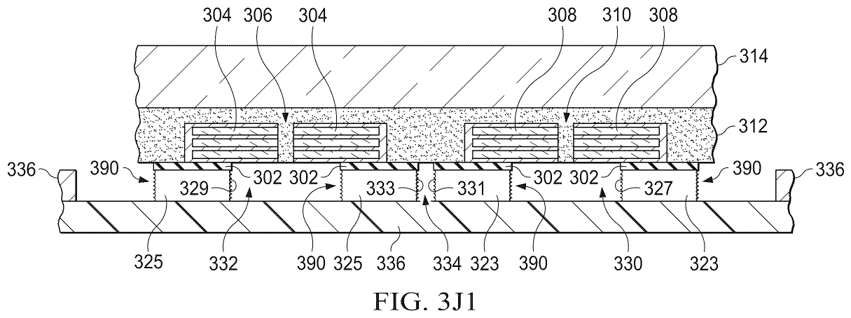

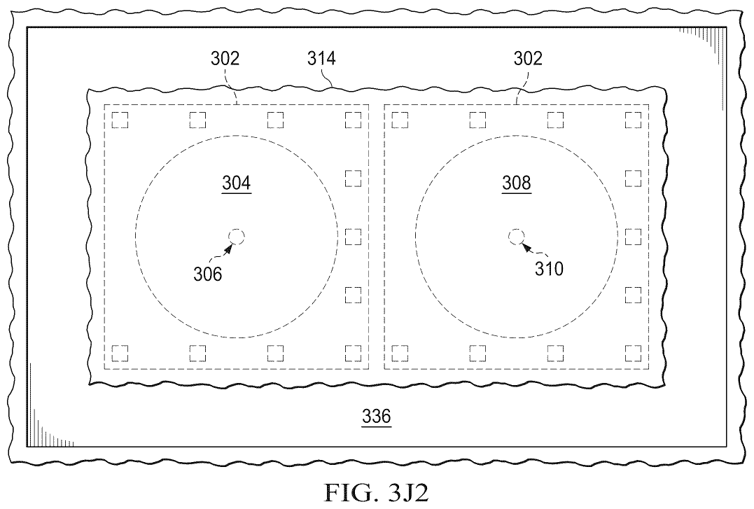

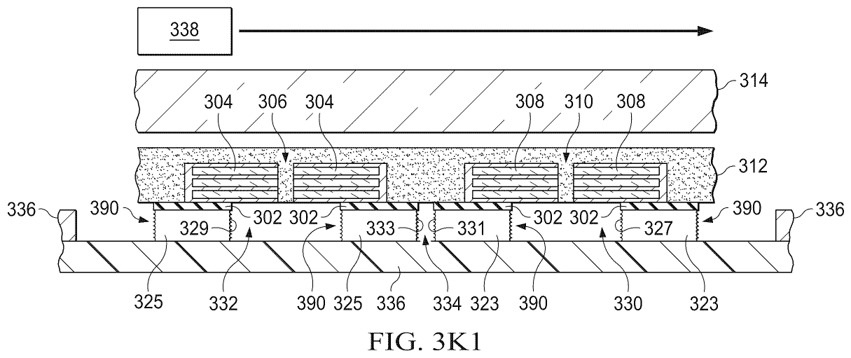

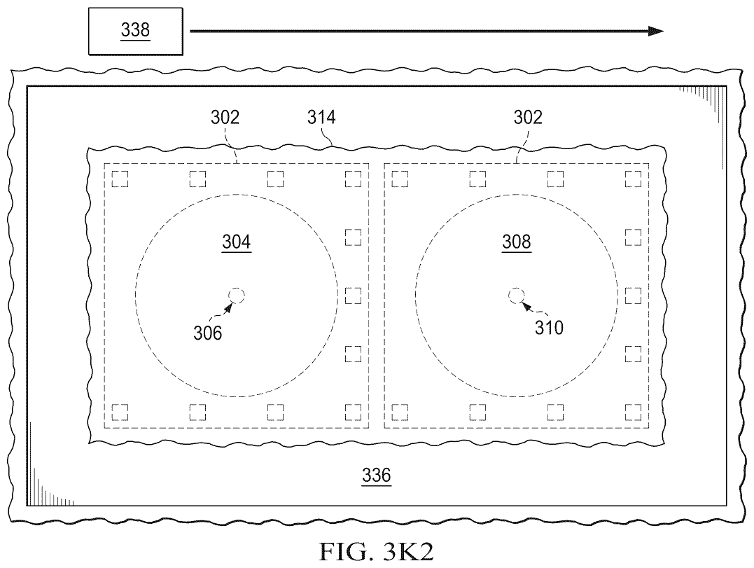

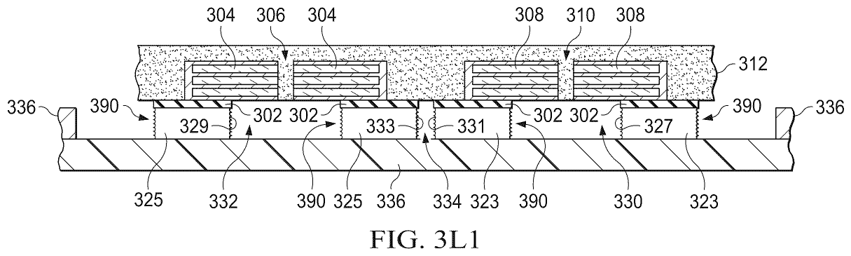

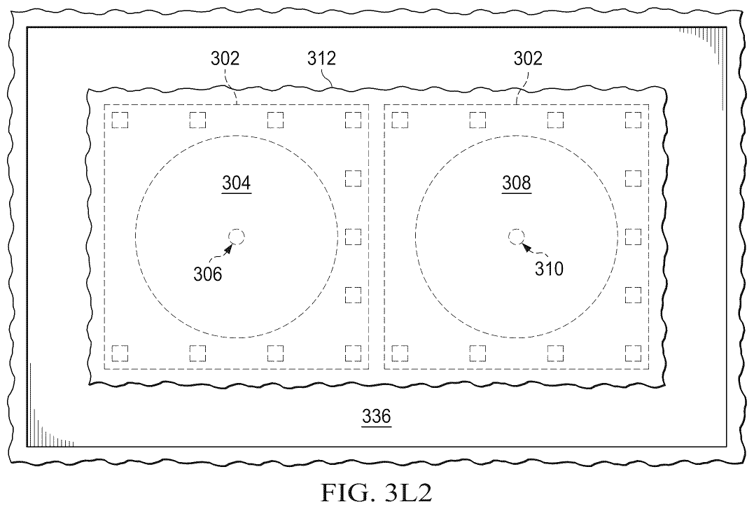

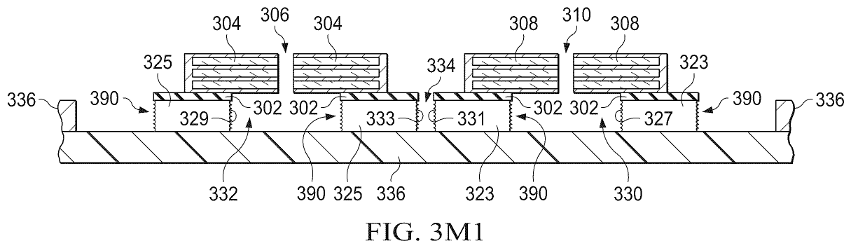

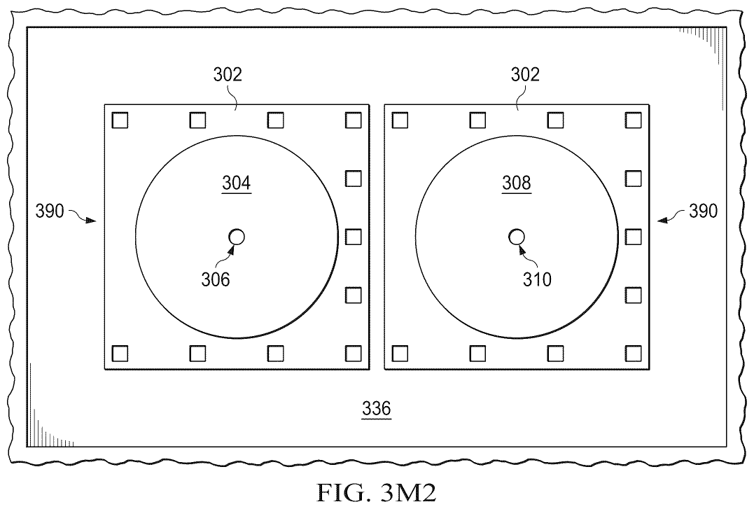

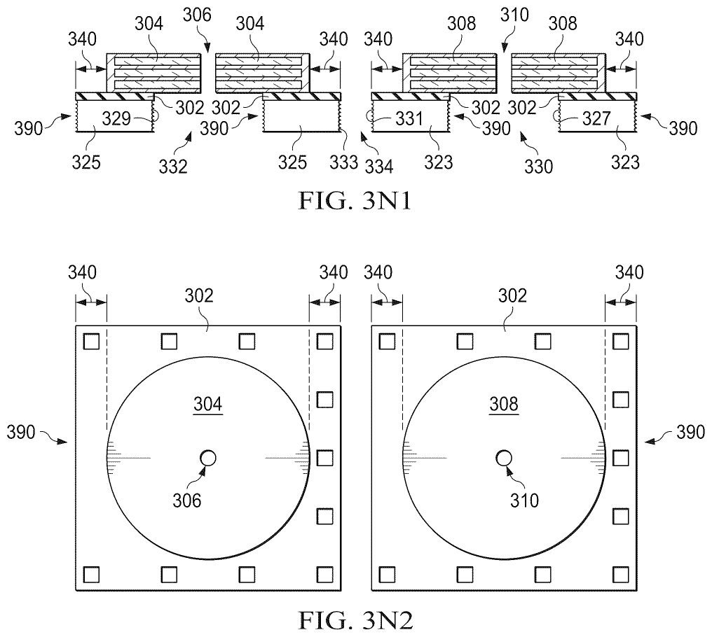

FIG. 2 is a flow diagram of a method 200 for manufacturing a semiconductor package with plasma-etched scallops, in accordance with various examples. FIGS. 3A1-3O are a process flow for manufacturing a semiconductor package with plasma-etched scallops, in accordance with various examples. Accordingly, FIGS. 2 and 3A1-3O are described in parallel.

The method 200 may include applying a wafer bond layer to a microelectromechanical systems (MEMS) membrane on a first surface of a semiconductor wafer and to an oxide layer on the first surface of the semiconductor wafer (202). FIG. 3A1 is a cross-sectional view of a structure including a semiconductor wafer 300 (e.g., silicon, gallium nitride), an oxide layer 302 contacting a top surface of the semiconductor wafer 300, and MEMS membranes 304 and 308 on the oxide layer 302. An opening 306 extends through a thickness of the MEMS membrane 304, for example, at a center of the MEMS membrane 304. Similarly, an opening 310 extends through a thickness of the MEMS membrane 308, for example, at a center of the MEMS membrane 308. In examples, the MEMS membranes 304, 308 are any suitable type of MEMS membrane or device, such as an acoustic membrane configured to detect acoustic waves (e.g., in a microphone). FIG. 3A2 is a top-down view of the structure of FIG. 3A1. FIG. 3B1 is a cross-sectional view of the structure of FIG. 3A1, except that a wafer bond layer 312 is applied to the MEMS membranes 304, 308 and to the oxide layer 302. The oxide layer 302 may be any suitable type of oxide layer, such as silicon dioxide, aluminum oxide, etc. The wafer bond layer 312 may be any suitable type of temporary wafer bond layer, such as a polymer bond layer. FIG. 3B2 is a top-down view of the structure of FIG. 3B1, in accordance with various examples.

The method 200 may include coupling a carrier wafer to the wafer bond layer (204). FIG. 3C1 is a cross-sectional view of the structure of FIG. 3B1, except that a carrier wafer 314 physically contacts the wafer bond layer 312. The carrier wafer 314 may be of any suitable type, such as borosilicate glass, fused silica or quartz glass, aluminosilicate glass, etc. The carrier wafer 314 may be coupled using any suitable adhesive, such as thermal release, ultraviolet release, or solvent soluble release adhesives. FIG. 3C2 is a top-down view of the structure of FIG. 3C1.

The method 200 may include coupling a photoresist layer to a second surface of the semiconductor wafer opposite the first surface (206). FIG. 3D1 is a cross-sectional view of the structure of FIG. 3C1, except that the structure is flipped upside down and has been backgrinded to thin the semiconductor wafer 300. FIG. 3D2 is a top-down view of the structure of FIG. 3D1 in the particular orientation of FIG. 3D1. FIG. 3E1 is a cross-sectional view of the structure of FIG. 3D1, except that a photoresist layer 316 physically contacts a surface of the semiconductor wafer 300 opposite that which the oxide layer 302 contacts. FIG. 3E2 is a top-down view of the structure of FIG. 3E1.

The method 200 may include patterning the photoresist layer to include a first opening above a first portion of the semiconductor wafer, a second opening above a second portion of the semiconductor wafer, and a third opening in between the first and second openings (208). FIG. 3F1 is a cross-sectional view of the structure of FIG. 3E1, except that the photoresist layer 316 includes an opening 318, and opening 320, and an opening 322 in between the openings 318 and 320. Various photolithography techniques may be useful to form the openings 318, 320, and 322. In examples, and as shown, the opening 322 is narrower than the openings 318 and 320. FIG. 3F2 is a top-down view of the structure of FIG. 3F1.

The method 200 may include simultaneously plasma etching (e.g., deep reactive ion etching (DRIE)) a first opening in the first portion through the first opening in the photoresist layer, a second opening in the second portion through the second opening in the photoresist layer, and a third opening in the semiconductor wafer between the first and second openings through the third opening in the photoresist layer (210). The plasma etching causes walls of the first, second, and third openings in the semiconductor wafer to be scalloped with multiple concavities having heights ranging from 20 nanometers to 1 micron, and the plasma etching of the third opening causes the first and second portions to separate from each other (210). FIG. 3G1 is a cross-sectional view of the structure of FIG. 3F1, except that an opening 324 is plasma etched in the semiconductor wafer 300 through the opening 318, an opening 326 is plasma etched in the semiconductor wafer 300 through the opening 320, and an opening 328 is plasma etched in the semiconductor wafer 300 through the opening 322. The formation of the opening 328 causes the semiconductor wafer 300 to become separated into individual semiconductor dies 323 and 325. The openings 324, 326, and 328 are etched to the oxide layer 302. Plasma etching the openings 324, 326, and 328 causes the walls 327, 329, 331, and 333 of the openings 324, 326, and 328 to become scalloped with multiple concavities 390. As described above, each of the concavities 390 has a height ranging from 20 nanometers to 1 micron. Because the opening 324 may be circular, each concavity 390 in the wall 327 forms a complete loop around the opening 324. Similarly, because the opening 326 is circular, each concavity 390 in the wall 327 forms a complete loop around the opening 326. Each concavity 390 in the wall 331 forms a complete loop around the four sides of the perimeter of the semiconductor die 323, because the external walls of the semiconductor die 323 are plasma etched at the same time and in the same manner. Similarly, each concavity 390 in the wall 333 forms a complete loop around the perimeter of the semiconductor die 325, because the external walls of the semiconductor die 325 are plasma etched at the same time and in the same manner. The number of concavities 390 on the external walls of the semiconductor die 323 is the same as the number of concavities 390 on the wall 327. In examples, the entirety of the external walls of the semiconductor die 323 is scalloped, and the entirety of the inner wall 327 is scalloped. In examples, the top and bottom surfaces of the semiconductor die 323 are not scalloped. FIG. 3G2 is a top-down view of the structure of FIG. 3G1.

The method 200 may include removing first, second, and third segments of the oxide layer from the first, second, and third openings, respectively (212). FIG. 3H1 is a cross-sectional view of the structure of FIG. 3G1, except that portions of the oxide layer 302 are removed (e.g., by wet or dry etching) through the openings 324, 326, and 328, as numerals 330, 332, and 334 indicate, respectively. If the portions of the oxide layer 302 are removed by wet etching, etch stops may be included in the oxide layer to prevent the wet etchant from etching away portions of the oxide layer that are directly below the semiconductor dies 323. FIG. 3H2 is a top-down view of the structure of FIG. 3H1.

The method 200 may include removing the photoresist layer, the carrier wafer, and the wafer bond layer (214). FIG. 311 is a cross-sectional view of the structure of FIG. 3H1, except that the photoresist layer 316 is removed, such as by a wet stripping or dry stripping technique. FIG. 3I2 is a top-down view of the structure of FIG. 3I1. FIG. 3J1 is a cross-sectional view of the structure of FIG. 3I1, except that the semiconductor dies 323, 325 are coupled to a flex frame 336. FIG. 3J2 is a top-down view of the structure of FIG. 3J1. FIG. 3K1 is a cross-sectional view of the structure of FIG. 3J1, except that a release technique (e.g., chemical or thermal release), represented by numeral 338, is applied to the carrier wafer 314 to dissolve and/or weaken the adhesive that is holding the carrier wafer 314 in place. The flex frame 336 is useful to provide mechanical support to the semiconductor dies 323, 325 during the release process, holding the semiconductor dies 323, 325 in place and preventing warping and cracking as the adhesive is weakened. After the adhesive is weakened and the carrier wafer 314 is peeled away, the flex frame 336 facilitates the mechanical integrity of the semiconductor dies 323, 325. FIG. 3K2 is a top-down view of the structure of FIG. 3K1. FIG. 3L1 represents the structure of FIG. 3K1 with the carrier wafer 314 removed. FIG. 3L2 is a top-down view of the structure of FIG. 3L1. FIG. 3M1 is a cross-sectional view of the structure of FIG. 3L1, except that the wafer bond layer 312 is removed, such as by using chemical (e.g., solvents such as acetone), mechanical, ultraviolet, or thermal techniques. FIG. 3M2 is a top-down view of the structure of FIG. 3M1.

The flex frame 336 is removed, as the cross-sectional view of FIG. 3N1 and the top-down view of FIG. 3N2 show. A distance 340 separates the outer edge of the MEMS membrane 304, 308 and the outer edge of the semiconductor die 325, 323, respectively, in the lateral (i.e., horizontal) direction. This distance 340 includes a first distance from the outer edge of the MEMS membrane 304, 308 to the active silicon clearance line, and a second distance from the active silicon clearance line to the outer edge of the semiconductor die 325, 323. The techniques described herein may not impact the first distance, but the techniques described herein substantially reduce the second distance, because the second distance is approximately half of the scribe street width of the semiconductor wafer 300, and, as described herein, the techniques described herein substantially reduce the semiconductor wafer 300 scribe street widths. Consequently, the semiconductor die 323, 325 size is reduced, which increases the yield per semiconductor wafer 300. The techniques described herein reduce the semiconductor wafer 300 scribe street width to 10 microns or less, with the aforementioned second distance portion of the distance 340 being 5 microns.

FIG. 3O is a more detailed view of the distance 340, in accordance with various examples. The distance 340 is from the outer edge of the MEMS membrane 304, 308 to the outer edge of the semiconductor die 325, 323 in the lateral direction. A distance 342 is from the outer edge of the MEMS membrane 304, 308 to the active silicon clearance, and a distance 344 is from the active silicon clearance to the outer edge of the semiconductor die 325, 323. The distance 344 is formerly part of the scribe street of the semiconductor wafer 300 and is now part of the semiconductor die 325, 323. The technique described herein may substantially reduce the scribe street width on the semiconductor wafer 300, and thus the post-singulation distance 344 is also substantially reduced and can be as small as 5 microns, thus significantly boosting semiconductor wafer 300 yield.

The method 200 may include coupling the first portion to a substrate (218) and covering the first portion and the substrate with a protective enclosure (220), thereby resulting in the structure of FIGS. 1A-IF, described above. Additional steps, such as wirebonding, also may be performed.

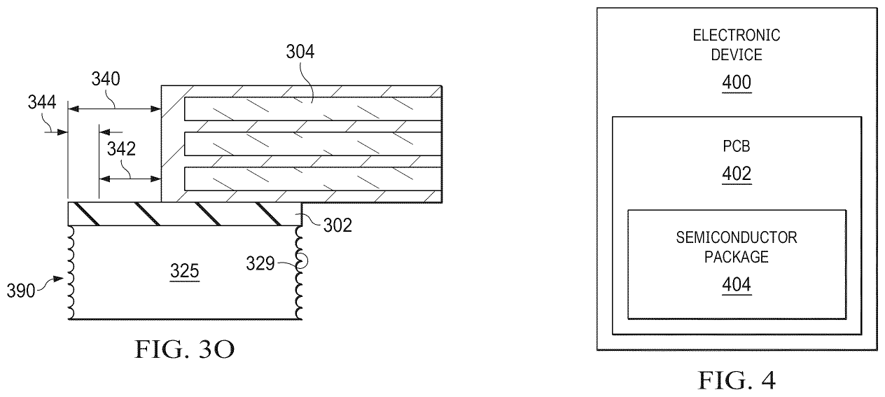

FIG. 4 is a block diagram of an electronic device including a semiconductor package with plasma-etched scallops, in accordance with various examples. Specifically, an electronic device 400 may include a printed circuit board (PCB) 402 to which a semiconductor package 404, such as the semiconductor package 100 (FIGS. 1A-1F), may be coupled. Examples of the electronic device 400 include an automobile, an aircraft, a watercraft, a spacecraft, a video game console, an arcade video game unit, a smartphone, an entertainment device, an appliance, a laptop computer, a desktop computer, a tablet, a notebook, or any other suitable type of electronic device or system.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a substrate including a first opening;
a first semiconductor die coupled to the substrate and including a microelectromechanical systems (MEMS) membrane, the first semiconductor die including a scalloped outer surface having multiple concavities;
a second semiconductor die coupled to the substrate and configured to control the first semiconductor die;
bond wires coupling the first and second semiconductor dies to the substrate; and
a protective enclosure covering the substrate, the first and second semiconductor dies, and the bond wires.

2. The semiconductor package of claim 1, wherein a horizontal distance between an active silicon clearance line and an edge of the first semiconductor die is approximately 5 microns.

3. The semiconductor package of claim 1, wherein the first semiconductor die has dimensions of approximately 1.4 millimeters by 1.4 millimeters.

4. The semiconductor package of claim 1, wherein the multiple concavities include one concavity that extends along four outer surfaces of the first semiconductor die.

5. The semiconductor package of claim 1, wherein a total number of the multiple concavities on the scalloped outer surface is identical to a total number of concavities on a scalloped inner surface of the first semiconductor die.

6. The semiconductor package of claim 1, wherein an entire outer surface of the first semiconductor die is scalloped.

7. The semiconductor package of claim 1, wherein the first semiconductor die includes a scalloped inner surface opposite the scalloped outer surface.

8. The semiconductor package of claim 7, wherein an entire inner surface of the first semiconductor die is scalloped.

9. The semiconductor package of claim 1, wherein top and bottom surfaces of the first semiconductor die are non-scalloped.

10. The semiconductor package of claim 1, wherein the MEMS membrane is configured to sense acoustic waves.

11. A semiconductor package, comprising:
a substrate;
a semiconductor die coupled to the substrate and having multiple scalloped outer lateral surfaces, a scalloped inner lateral surface, a non-scalloped top surface, and a non-scalloped bottom surface, wherein the multiple scalloped outer lateral surfaces include a concavity that continuously extends along each of the multiple scalloped outer lateral surfaces; and
a protective enclosure covering the substrate and the semiconductor die.

12. The semiconductor package of claim 11, wherein a horizontal distance between an active silicon clearance line and an edge of the semiconductor die is approximately 5 microns.

13. The semiconductor package of claim 11, wherein each of the multiple scalloped outer lateral surfaces and the scalloped inner lateral surface include multiple concavities, each of the multiple concavities ranging from 20 nanometers to 1 micron in height.

14. The semiconductor package of claim 11, wherein a first concavity on the multiple scalloped outer lateral surfaces extends along an entire outer lateral surface, and wherein a second concavity on the scalloped inner lateral surface extends along an entire circumference of the scalloped inner lateral surface.

15. The semiconductor package of claim 11, wherein an entire outer lateral surface of the semiconductor die is scalloped.

16. The semiconductor package of claim 11, wherein an entire inner lateral surface of the semiconductor die is scalloped.

17. The semiconductor package of claim 11, further comprising a microelectromechanical systems (MEMS) membrane coupled to the non-scalloped top surface, the MEMS membrane configured to sense acoustic waves.

18. A method for manufacturing a semiconductor package, comprising:
coupling a photoresist layer to a semiconductor wafer;
patterning the photoresist layer to include a first opening above a first portion of the semiconductor wafer, a second opening above a second portion of the semiconductor wafer, and a third opening between the first and second openings;
simultaneously plasma etching a first opening in the first portion through the first opening in the photoresist layer, a second opening in the second portion through the second opening in the photoresist layer, and a third opening in the semiconductor wafer between the first and second openings through the third opening in the photoresist layer, the plasma etching causing walls of the first, second, and third openings in the semiconductor wafer to be scalloped with a same number of concavities, and the plasma etching of the third opening causing the first and second portions to separate from each other;
removing the photoresist layer;
coupling the first portion to a substrate; and
covering the first portion and the substrate with a protective enclosure.

19. The method of claim 18, wherein a scribe width in the semiconductor wafer in which the third opening is formed is 10 microns or less.

20. The method of claim 18, wherein the plasma etching comprises a deep reactive ion etching (DRIE) process.

21. The method of claim 18, wherein the plasma etching causes an entirety of each of the walls to be scalloped.

22. The method of claim 18, wherein at least one of the concavities extends along an entire length of one of the walls of the third opening.

23. The method of claim 18, wherein top and bottom surfaces of the semiconductor wafer, which are orthogonal to the walls, are non-scalloped.

24. The method of claim 18, wherein heights of the concavities range from 20 nanometers to 1 micron.

25. A method for manufacturing a semiconductor package, comprising:
applying a wafer bond layer to a microelectromechanical systems (MEMS) membrane on a first surface of a semiconductor wafer and to an oxide layer on the first surface of the semiconductor wafer;
coupling a carrier wafer to the wafer bond layer;
coupling a photoresist layer to a second surface of the semiconductor wafer opposite the first surface;
patterning the photoresist layer to include a first opening above a first portion of the semiconductor wafer, a second opening above a second portion of the semiconductor wafer, and a third opening between the first and second openings;
simultaneously plasma etching a first opening in the first portion through the first opening in the photoresist layer, a second opening in the second portion through the second opening in the photoresist layer, and a third opening in the semiconductor wafer between the first and second openings through the third opening in the photoresist layer, the plasma etching causing walls of the first, second, and third openings in the semiconductor wafer to be scalloped with multiple concavities having heights ranging from 20 nanometers to 1 micron, and the plasma etching of the third opening causing the first and second portions to separate from each other;
removing first, second, and third segments of the oxide layer from the first, second, and third openings, respectively;
removing the photoresist layer, the carrier wafer, and the wafer bond layer;
coupling the first portion to a substrate; and
covering the first portion and the substrate with a protective enclosure.

26. The method of claim 25, wherein a scribe width in the semiconductor wafer in which the third opening is formed is approximately 10 microns.

27. The method of claim 25, wherein the first, second, and third openings are arranged consecutively with no other openings therebetween.
